(19) United States
(12) Patent Application Publication
(10) Pub. No.: US 2025/0306479 A1
(43) Pub. Date: Oct. 2, 2025

(54) OPTICAL SYSTEM AND PROJECTION EXPOSURE APPARATUS

(71) Applicant: Carl Zeiss SMT GmbH, Oberkochen (DE)

(72) Inventors: Sebastian HENSELER, Aalen (DE); Tobias HEGELE, Aalen (DE); Dietmar DUERR, Dettingen (DE); Johannes KRUIS, Oberkochen (DE); Christian WERNER, BB Beek en Donk (NL)

(21) Appl. No.: 19/240,940

(22) Filed: Jun. 17, 2025

Related U.S. Application Data
(63) Continuation of application No. PCT/EP2023/086643, filed on Dec. 19, 2023.

(30) Foreign Application Priority Data
Dec. 21, 2022 (DE) 10 2022 214 186.5

(51) Int. Cl. G03F 7/00

(52) U.S. Cl. CPC G03F 7/70825

(57) ABSTRACT

An optical system for a projection exposure apparatus comprises an optical element and a mount, which carries the optical element. The mount comprises an outer ring, in which the optical element is accommodated at least in portions. The outer ring comprises securing portions which are cohesively connected to the optical element. The securing portions are pivotably connected to the outer ring with the aid of joint portions. The mount comprises a tool interface for releasably securing a tool for swapping the optical system from an illumination optical unit.

### CROSS-REFERENCE TO RELATED APPLICATIONS

The present application is a continuation of, and claims benefit under 35 USC 120 to, international application No. PCT/EP2023/086643, filed Dec. 19, 2023, which claims benefit under 35 USC 119 of German Application No. 10 2022 214 186.5, filed Dec. 21, 2022. The entire disclosure of each of these applications is incorporated by reference herein.

### FIELD

The present disclosure relates to an optical system and to a projection exposure apparatus comprising such an optical system.

### BACKGROUND

Microlithography is used for producing microstructured components, for example integrated circuits. The microlithography process is carried out using a lithography apparatus, which has an illumination system and a projection system. The image of a mask (reticle) illuminated via the illumination system is projected via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, DUV lithography apparatuses (deep ultraviolet, DUV) are currently under development, which use light having a wavelength in the range of 30 nanometers (nm) to 250 nm, such as 193 nm. In the case of such DUV lithography apparatuses, reflective optical units, that is to say mirrors, can be used instead of, as hitherto, refractive optical units, that is to say lens elements.

Such a mirror can be accommodated in a mount. Such a mount is usually fixedly installed, for example in a projection system as mentioned above. Accordingly, no provision is made for swapping the mount together with the mirror. Furthermore, the mount itself may apply tensioning forces to the mirror which may lead to unwanted stresses in the mirror and thus to changes in the optical properties of the mirror. It would be desirable to improve this.

### SUMMARY

The present disclosure seeks to provide an improved optical system.

Accordingly, an optical system for a projection exposure apparatus is proposed. The optical system comprises an optical element and a mount, which carries the optical element, wherein the mount comprises an outer ring, in which the optical element is accommodated at least in portions, wherein the outer ring comprises securing portions which are cohesively connected to the optical element, and wherein the securing portions are pivotably connected to the outer ring with the aid of joint portions. In this case, the mount comprises a tool interface for releasably securing a tool for swapping the optical system from an illumination optical unit.

By virtue of the fact that the mount is cohesively connected to the optical element and carries the latter, the mount together with the optical element can be swapped. The pivotable securing portions can help ensure that tensioning forces introduced into the optical element by the mount are significantly reduced, thereby potentially preventing unwanted material stresses in the optical element.

The optical system is, for example, a mirror, such as an EUV mirror, or a mirror module, or can be referred to as such. The optical system can be a mirror in a catadioptric system. The optical system can be part of a projection optical unit. The projection optical unit can comprise a plurality of such optical systems. However, the optical system can also be part of an illumination system. However, it is assumed below that the optical system is part of a projection optical unit. The optical system can be suitable for EUV lithography. However, the optical system can also be suitable for DUV lithography.

A coordinate system comprising a first spatial direction or x-direction, a second spatial direction or y-direction and a third spatial direction or z-direction can be assigned to the optical system. The optical system has an axis of symmetry or centre axis which is oriented parallel to the z-direction or coincides therewith. The optical system can be constructed substantially rotationally symmetrically with respect to the centre axis. However, this is not mandatory. A radial direction of the optical system is oriented perpendicularly to the centre axis and away from the latter.

The optical system can be swappable. That is to say that the optical system can be removed from the projection optical unit and inserted again into the latter. The optical system can therefore also be referred to as an optical swapping system or optical swapping module. A corresponding tool can be provided for swapping the optical system. The optical system can be swapped in the field. In the present case, “in the field” means in particular that swapping the optical system can be carried out directly at an operating site of a projection exposure apparatus comprising such an optical system. In this case, the optical system is swapped in its entirety. That is to say, in particular, that the optical element together with the mount is swapped. The swapped optical system can be replaced with a newly developed optical system having an improved optical effect, whereby the performance and/or accuracy of the projection optical unit can also be increased. The newly developed optical system can also include electronic components, inter alia.

The optical system can comprise exactly one optical element and exactly one mount. The optical element can be a mirror or a lens element. It is assumed below that the optical element is a mirror. The optical element comprises an optically effective surface. The optically effective surface is suitable for reflecting illumination radiation, such as DUV radiation, during operation of the optical system. A reflectivity at 193 nm is used in this case. However, the optically effective surface can also be suitable for reflecting EUV radiation. The optically effective surface is accordingly a mirror surface. The optically effective surface can be realized with the aid of a coating. The optical element comprises a mirror substrate, at which the optically effective surface is provided. The mirror substrate can be produced for example from glass, glass ceramic, ceramic, silicon or the like. The optically effective surface can be curved, for example curved in the shape of a spherical cap or toroidally curved. The curvature of the optically effective surface can be of both spherical and aspherical nature.

The optical element can have a rear side facing away from the optically effective surface. The rear side, too, can be curved. The rear side does not have defined surface properties. That is to say for example that the rear side is not a mirror surface and therefore does not have reflective properties either. An outer surface of the optical element is provided between the optically effective surface and the rear side. The outer surface can be cylindrical. The outer surface can be constructed rotationally symmetrically with respect to the centre axis. The outer surface can extend circumferentially completely around the optical element. The optical element can be constructed rotationally symmetrically with respect to the centre axis. However, this is not mandatory.

In the present case, the fact that the mount “carries” the optical element means, in particular, that the optical element is fixedly connected to the mount, and that the optical element can be adjusted or aligned together with the mount. In particular, the mount takes up a weight force of the optical element. The mount can be a one-piece component, in particular one which is materially in one piece. “In one piece” or “integrally” here means in particular that the mount is not composed of different subordinate components, but rather that the outer ring, the securing portions and the joint portions form a common component, namely the mount. “Materially in one piece” means here in particular that the mount is produced from the same material throughout. For example, the mount can be produced from copper, aluminium, steel or the like. The mount can be produced with the aid of an additive or generative production method, such as with the aid of a 3D printing method. Furthermore, the mount can also be produced with the aid of an erosion method.

The outer ring can be constructed rotationally symmetrically with respect to the centre axis. However, this is not mandatory. The outer ring can also be elliptic or oval, for example. For example, the outer ring comprises a plurality of outer ring segments which are connected to one another in one piece. The outer ring segments form planar or straight portions of the outer ring. The outer ring is therefore optionally not circular, but rather polygonal. Accordingly, in the present case, a “ring” should be understood to mean in particular a closed geometry extending circumferentially completely around the centre axis. A “ring” is accordingly not necessarily circular in the present case. The outer ring is configured to extend circumferentially around the outer surface of the optical element. That is to say, for example, that the outer ring extends circumferentially completely around the centre axis and includes or encloses the outer surface of the optical element.

The securing portions can be part of the outer ring. The securing portions are connected to the outer ring in one piece for example with the aid of the joint portions. For example, the outer ring is cohesively connected to the outer surface of the optical element with the aid of the securing portions. In cohesive connections, the connection partners are held together by atomic or molecular forces. Cohesive connections are non-releasable connections that can be separated only by destruction of the connection mechanism and/or the connection partners. A cohesive connection can be implemented by adhesive bonding, for example.

That is to say that the outer ring can be adhesively bonded to the optical element, such as to the outer surface of the optical element. For example, the securing portions of the outer ring are adhesively bonded to the optical element, such as to the outer surface thereof. For this purpose, an adhesive bond is provided at each securing portion. Accordingly, rather than one adhesive bond extending circumferentially completely around the axis of symmetry, a plurality of adhesive bonds separate from one another are provided at the outer surface, each adhesive bond being assigned a securing portion. The adhesive bonds are each provided between a joining surface of the respective securing portion and the outer surface of the optical element and cohesively connect the respective joining surface to the outer surface.

The joint portions can be flexures. By way of example, exactly one joint portion can be assigned to each securing portion. Alternatively, it is also possible for a plurality of joint portions, for example two, to be assigned to each securing portion. In the present case, a “flexure” should be understood to mean generally a region, for example a cross-sectional narrowing or thinning, of a component, in the present case the outer ring or the respective outer ring segment, which region enables a relative movement between two rigid-body regions of the component by bending or torsion. What function as rigid-body regions here are the securing portion and the outer ring, for example, between which the respective joint portion is provided in the form of a cross-sectional narrowing or thinning.

By adapting the stiffness of the joint portion, the properties thereof, for example the deformability thereof, can be adapted. In the present case, the “stiffness” should be understood to mean very generally the resistance of a body, in the present case the joint portion, to an elastic deformation imposed thereon by an external load and conveys the relationship between the load on the body and its deformation. The stiffness is determined by the material of the body and its geometry. For example, the stiffness of the joint portion can be adapted as desired by way of different cross-sectional geometries. The joint portions can help ensure a mechanical decoupling of the optical element from the mount. In the present case, a “mechanical decoupling” should be understood to mean that the joint portions prevent or at least reduce the transmission of forces from the mount to the optical element.

In accordance with one embodiment, the joint portions are configured to enable a pivot movement of the securing portions in a radial direction of the optical system.

A pivot axis of the respective joint portion is accordingly oriented parallel to the z-direction or to the centre axis. With the aid of the joint portions, it is thus possible for example to compensate for a heat-dictated expansion of the optical element and/or of the mount along the radial direction. Each joint portion thus enables a movement of the securing portion assigned to the respective joint portion along the radial direction outwards away from an inner ring of the mount.

In accordance with an embodiment, each securing portion comprises a joining surface facing the optical element, the joining surface being cohesively connected to the optical element, wherein normals to the joining surfaces intersect one another in a centre axis of the optical system.

The centre axis is an optical axis of the optical system or can be referred to as such. The joining surfaces can be flat or straight in each case. In the present case, a “normal” should be understood to mean a straight line oriented perpendicularly to the respective joining surface. All normals to all joining surfaces of all securing portions can intersect one another in the centre axis.

In accordance with a further embodiment, each securing portion is pivotably connected to the outer ring with the aid of a first joint portion and with the aid of a second joint portion different from the first joint portion.

Alternatively, it is also possible for exactly one joint portion to be provided. That is to say, for example, that the second joint portion is optional. Providing two joint portions can help allow for an optimized decoupling of the optical element to be attained. It is also possible for more than two joint portions to be provided.

In accordance with an embodiment, each securing portion is pivotably connected to a connecting portion with the aid of the first joint portion, wherein the connecting portion is pivotably connected to the outer ring with the aid of the second joint portion.

For example, the connecting portion is pivotably connected to a base portion of the outer ring with the aid of the second joint portion. Accordingly, the securing portion is connected to the outer ring, such as to the base portion of the outer ring, only via the first joint portion, the connecting portion and the second joint portion. The connecting portion can be parallelepipedal. In comparison with the two joint portions, the connecting portion has a significantly greater stiffness. The connecting portion thus functions as a rigid-body region between the first joint portion and the second joint portion.

In accordance with a further embodiment, the optical element comprises an optically effective surface, such as a mirror surface, a rear side facing away from the optically effective surface, and an outer surface extending circumferentially around the optical element, wherein the securing portions are only cohesively connected to the outer surface.

That is to say, for example, that the mount is cohesively connected to the optical element exclusively with the aid of the adhesive bonds provided at the securing portions. The mount accordingly can contact the optical element exclusively with the securing portions or with the adhesive bonds provided at the latter. Further contact points between the mount and the optical element accordingly might not be provided.

In accordance with a further embodiment, the mount comprises an inner ring arranged within the outer ring, wherein the inner ring is connected to the outer ring with the aid of stiffening ribs.

Conversely, the inner ring can also be arranged outside the outer ring. As viewed along the radial direction, the inner ring is arranged within the outer ring or the outer ring is arranged outside the inner ring. The inner ring can be provided at the rear side of the optical element. The inner ring can be arranged spaced apart from the rear side as viewed along the centre axis, such that the inner ring does not contact the rear side. The stiffening ribs can also be referred to as stiffening webs. The outer ring can be stiffened with the aid of the inner ring and the stiffening ribs, the stiffening being shifted to the rear side of the optical element. A significant reduction of the installation space used for the optical system can be attained as a result.

In accordance with an embodiment, two stiffening ribs are always connected to the outer ring at a common outer joining point.

As viewed along a circumferential direction of the optical system, a respective outer joining point is arranged centrally between two normals-as mentioned above-to adjacent securing portions. Conversely, a respective normal is positioned between two adjacent outer joining points. At the outer joining points, the stiffening ribs are connected to the outer ring in one piece, in particular materially in one piece.

In accordance with a further embodiment, the outer joining points and the securing portions are arranged alternately.

That is to say, for example, that as viewed along the circumferential direction of the mount or the optical system, in each case an outer joining point is arranged between securing portions or a securing portion is arranged between two outer joining points.

In accordance with an embodiment, the securing portions are each positioned centrally between two adjacent outer joining points.

As mentioned above, the normal to each securing portion accordingly runs centrally between two adjacent outer joining points in the direction of the centre axis in order to intersect the latter.

In accordance with an embodiment, two stiffening ribs are always connected to the inner ring at a common inner joining point, wherein the outer joining points and the inner joining points are arranged alternately.

The outer joining points and the inner joining points are arranged alternately as viewed along the circumferential direction. The abovementioned normals to the securing portions run through the inner joining points. At the inner joining points, the stiffening ribs are connected to the inner ring in one piece, for example materially in one piece. An inner joining point is always arranged between two outer joining points and an outer joining point is always arranged between two inner joining points as viewed along the circumferential direction.

In accordance with an embodiment, the mount comprises vibration absorber interfaces for joining vibration absorbers to the mount.

A plurality of vibration absorber interfaces can be provided, arranged in a manner distributed uniformly around the centre axis. Three vibration absorber interfaces can be arranged offset by 120° with respect to one another are provided. The vibration absorber interfaces are each provided in the region of an outer joining point, such that the vibration absorber interfaces are stiffened with the aid of the stiffening ribs. The vibration absorber can be part of the optical system. Each vibration absorber interface can be assigned a vibration absorber. Vibrations introduced into the optical system can be damped with the aid of the vibration absorbers.

In accordance with an embodiment, the mount comprises mount strut interfaces for joining mount struts to the mount.

A plurality of mount strut interfaces can be provided. For example, three mount strut interfaces arranged offset by 120° with respect to one another are provided. The vibration absorber interfaces and the mount strut interfaces can be arranged alternately as viewed along the circumferential direction. That is to say, for example, that a mount strut interface is arranged between two vibration absorber interfaces and a vibration absorber interface is arranged between two mount strut interfaces. Each mount strut interface can be assigned an outer joining point. This has the effect that the mount strut interfaces are stiffened with the aid of the stiffening ribs joined to the outer joining points. The mount struts are so-called “A struts” or can be referred to as such. The mount is seated on six spatial points. In this case, each mount strut is assigned two of these spatial points. With the aid of the mount struts, the mount or the optical system is operatively connected to a fixed world, such as a force frame, for example. In this case, the mount struts mechanically decouple the optical system from the fixed world, such that no unwanted stresses are introduced into the optical system.

The mount comprises a tool interface for releasably securing a tool for swapping the optical system from an illumination optical unit.

The tool interface can comprise a plurality of interface surfaces arranged parallel to one another. Each interface surface can be assigned a threaded hole, with the aid of which the tool can be connected to the tool interface. Exactly three interface surfaces can be provided. A first interface surface, a second interface surface and a third interface surface are provided. As viewed along the z-direction, the first interface surface and the second interface surface are positioned at the same height. The third interface surface is arranged below the second interface surface as viewed along the z-direction.

Furthermore, a projection exposure apparatus comprising such an optical system is proposed.

The projection exposure apparatus can comprise a plurality of such optical systems. The optical system can be part of a projection optical unit of the projection exposure apparatus. However, the optical system can also be part of an illumination system. The projection exposure apparatus can be an EUV lithography apparatus. EUV stands for “extreme ultraviolet” and refers to a wavelength of the working light of between 0.1 nm and 30 nm. The projection exposure apparatus can also be a DUV lithography apparatus. DUV stands for “deep ultraviolet” and refers to a wavelength of the working light of between 30 nm and 250 nm.

“A” or “an” or “one” in the present case should not necessarily be understood to be restrictive to exactly one element. Rather, a plurality of elements, such as two, three or more, can also be provided. Nor should any other numeral used here be understood to the effect that there is a restriction to exactly the stated number of elements. Rather, unless indicated otherwise, numerical deviations upwards and downwards are possible.

The embodiments and features described for the optical system apply correspondingly to the proposed projection exposure apparatus, and vice versa.

Further possible implementations of the disclosure also encompass not explicitly mentioned combinations of features or embodiments that are described above or hereinafter with respect to the exemplary embodiments. In this case, a person skilled in the art will also add individual aspects as improvements or supplementations to the respective basic form of the disclosure.

Further features, configurations and aspects of the disclosure are the subject of the dependent claims and also of the exemplary embodiments of the disclosure that are described hereinafter. The disclosure is explained in greater detail hereinafter on the basis of certain embodiments with reference to the accompanying figures.

### BRIEF DESCRIPTION OF THE DRAWINGS

FIG. 1 shows a schematic view of an embodiment of a projection exposure apparatus for DUV projection lithography;

FIG. 2 shows a schematic plan view of an embodiment of an optical system for the projection exposure apparatus in accordance with FIG. 1;

FIG. 3 shows a schematic rear view of the optical system in accordance with FIG. 2;

FIG. 4 shows the detail view IV in accordance with FIG. 2;

FIG. 5 shows the view V in accordance with FIG. 4;

FIG. 6 shows a schematic view of an embodiment of a vibration absorber for the optical system in accordance with FIG. 2; and

FIG. 7 shows a schematic view of an embodiment of a tool interface for the optical system in accordance with FIG. 2.

### DETAILED DESCRIPTION

Unless indicated otherwise, elements that are identical or functionally identical have been provided with the same reference signs in the figures. It should also be noted that the illustrations in the figures are not necessarily true to scale.

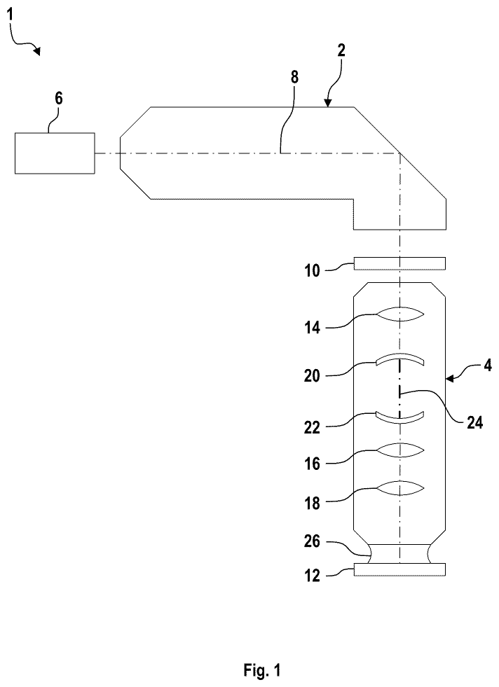

FIG. 1 shows a schematic view of a projection exposure apparatus 1, in particular of a DUV lithography apparatus, comprising a beam shaping and illumination system 2 (also referred to here as “illumination optical unit”) and a projection optical unit 4 (also referred to here as “projection lens”). In this case, DUV stands for “deep ultraviolet” and denotes a wavelength of the working light of between 30 nm and 250 nm.

The beam shaping and illumination system 2 and the projection optical unit 4 can each be arranged in a vacuum housing (not shown). Each vacuum housing is evacuated with the aid of an evacuation apparatus (not illustrated). The vacuum housings are surrounded by a machine room (not illustrated), in which driving apparatuses for mechanically moving or setting optical elements can be provided. Furthermore, electrical controllers and the like can also be arranged in the machine room.

The projection exposure apparatus 1 has a light source 6. For example, an ArF excimer laser that emits radiation 8 in the DUV range, at for example 193 nm, can be provided as the light source 6. In the beam shaping and illumination system 2, the radiation 8 is focused and a desired operating wavelength (working light) is filtered out from the radiation 8. The beam shaping and illumination system 2 can have optical elements which are not illustrated, for example mirrors or lens elements.

After passing through the beam shaping and illumination system 2, the radiation 8 is guided onto a photomask, or reticle 10. The photomask 10 is formed as a transmissive optical element and can be arranged outside the beam shaping and illumination system 2 and the projection optical unit 4. The photomask 10 has a structure which is imaged on a wafer 12 in reduced form via the projection optical unit 4.

The projection optical unit 4 has a plurality of lens elements 14, 16, 18 and/or mirrors 20, 22 for imaging the photomask 10 onto the wafer 12. In this case, individual lens elements 14, 16, 18 and/or mirrors 20, 22 of the projection optical unit 4 can be arranged symmetrically relative to an optical axis 24 of the projection optical unit 4. It should be noted that the number of lens elements 14, 16, 18 and mirrors 20, 22 shown here is purely by way of example and is not restricted to the number shown. A greater or lesser number of lens elements 14, 16, 18 and/or mirrors 20, 22 can also be provided.

An air gap between a last lens element (not shown) and the wafer 12 can be replaced by a liquid medium 26 which has a refractive index of >1. The liquid medium 26 can be for example high-purity water. Such a set-up is also referred to as immersion lithography and has an increased photolithographic resolution. The medium 26 can also be referred to as an immersion liquid.

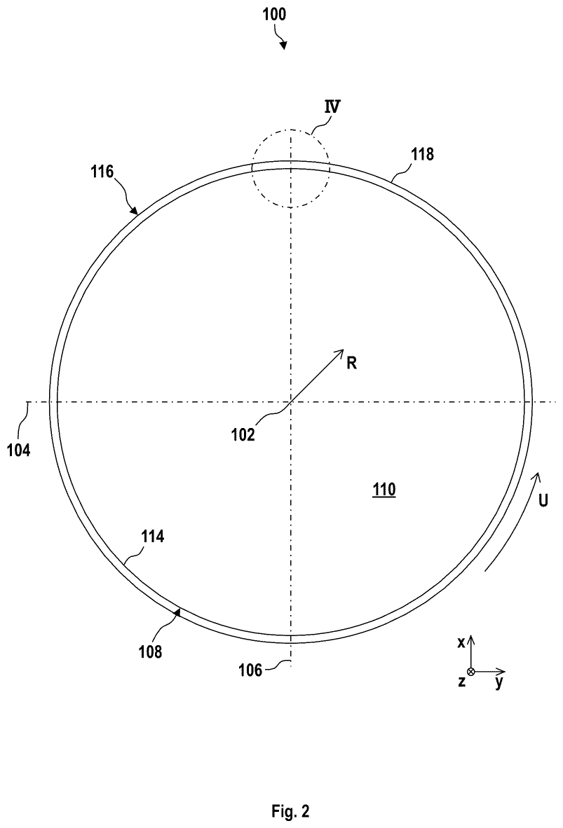

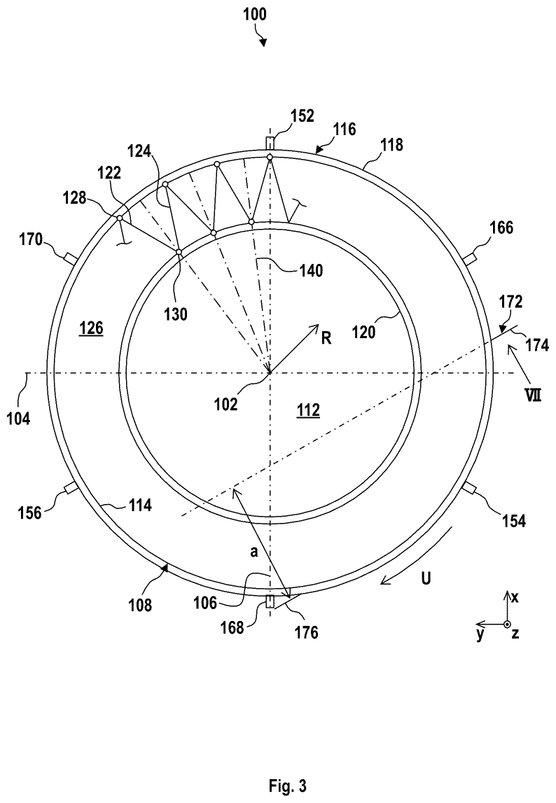

FIG. 2 shows a schematic plan view of an embodiment of an optical system 100 for the projection exposure apparatus 1. FIG. 3 shows a schematic rear view of the optical system 100. In the following text, reference is made to FIGS. 2 and 3 simultaneously.

The optical system 100 can be part of a projection optical unit 4 as explained above. However, the optical system 100 can also be part of a beam shaping and illumination system 2. However, it is assumed below that the optical system 100 is part of a projection optical unit 4 of this type. The optical system 100 is suitable for DUV lithography. However, the optical system 100 can also be suitable for EUV lithography.

The optical element 100 can be one of the mirrors 20, 22. The optical system 100 can accordingly be a mirror or a mirror module or can be referred to as such. The optical system 100 can be assigned the coordinate system comprising the x-direction x, the y-direction y and the z-direction z. The optical system 100 has an axis of symmetry or centre axis 102 which is oriented parallel to the z-direction z or coincides therewith. The optical system 100 can be constructed substantially rotationally symmetrically with respect to the centre axis 102. The optical system 100 is assigned two half axes 104, 106 which intersect the centre axis 102. A radial direction R of the optical system 100 is oriented perpendicularly to the centre axis 102 and away from the latter. A circumferential direction U is oriented around the centre axis 102.

The optical system 100 is swappable. That is to say that the optical system 100 can be removed from the projection optical unit 4 explained and inserted again into the latter. For this purpose, a corresponding tool (not shown) can be provided. The optical system 100 can be swapped in the field. In the present case, “in the field” means directly at the operating site of the projection exposure apparatus 1.

The optical system 100 has an optical element 108. The optical element 108 can be a mirror or a lens element. It is assumed below that the optical element 108 is a mirror. The optical element 108 has an optically effective surface 110. The optically effective surface 110 is suitable for reflecting illumination radiation 16, such as EUV radiation, during operation of the optical system 100. The optically effective surface 110 is a mirror surface. The optically effective surface 110 can be realized with the aid of a coating.

The optical element 108 has a rear side 112 facing away from the optically effective surface 110. The rear side 112 does not have defined surface properties. That is to say for example that the rear side 112 is not a mirror surface and therefore does not have reflective properties either. An outer surface 114 of the optical element 108 is provided between the optically effective surface 110 and the rear side 112. The outer surface 114 can be cylindrical. The outer surface 114 can be constructed rotationally symmetrically with respect to the centre axis 102.

In addition to the optical element, the optical system 100 has a mount 116, which carries the optical element 108. The mount 116 has an outer ring 118 and an inner ring 120. The circumferential direction U runs along the outer ring 118 or along the inner ring 120. The outer ring 118 and the inner ring 120 can each be constructed rotationally symmetrically with respect to the centre axis 102. As viewed along the radial direction R, the inner ring 120 is arranged within the outer ring 118 or the outer ring 118 is arranged outside the inner ring 120. The outer ring 118 and the inner ring 120 can each have a hollow-cylindrical or a tubular geometry.

The outer ring 118 is connected to the optical element 108, for example to the outer surface 114. For this purpose, a cohesive connection can be provided. In cohesive connections, the connection partners are held together by atomic or molecular forces. Cohesive connections are non-releasable connections that can be separated only by destruction of the connection mechanism and/or the connection partners. A cohesive connection can be implemented by adhesive bonding, for example. That is to say that the outer ring 118 can be adhesively bonded to the optical element 108, for example to the outer surface 114.

The inner ring 120 is not connected to the optical element 108. In the orientation of FIG. 3, the inner ring 120 is arranged above the rear side 112 of the optical element 108, but does not contact the rear side. That is to say that an air gap can be provided between the rear side 112 and the inner ring 120.

The inner ring 120 is connected to the outer ring 118 with the aid of stiffening webs or stiffening ribs 122, 124, of which only two are provided with a reference sign. The stiffening ribs 122, 124 are therefore arranged between the inner ring 120 and the outer ring 118, as viewed along the radial direction R, and span an interspace 126 provided between the outer ring 118 and the inner ring 120. The number of stiffening ribs 122, 124 is arbitrary in principle. The stiffening ribs 122, 124 run obliquely between the outer ring 118 and the inner ring 120. The stiffening ribs 122, 124 run completely around the centre axis 102.

In each case two stiffening ribs 122, 124 are joined to the outer ring 118 at an outer or first joining point 128. Accordingly, in each case two stiffening ribs 122, 124 are joined to the inner ring 120 at an inner or second joining point 130. That is to say that in each case two stiffening ribs 122, 124 meet at the outer joining point 128 and in each case two stiffening ribs 122, 124 meet at the inner joining point 130.

The mount 116 is a one-piece component, in particular one which is materially in one piece. “In one piece” or “integrally” here means in particular that the mount 116 is not composed of different subordinate components, but rather that the outer ring 118, the inner ring 120 and the stiffening ribs 122, 124 form a common component, namely the mount 116. “Materially in one piece” means here in particular that the mount 116 is produced from the same material throughout. For example, the mount 116 can be produced from copper, aluminium, steel or the like. The mount 116 can be produced with the aid of an additive or generative production method, such as with the aid of a 3D printing method. Furthermore, the mount 116 can also be produced with the aid of an erosion method.

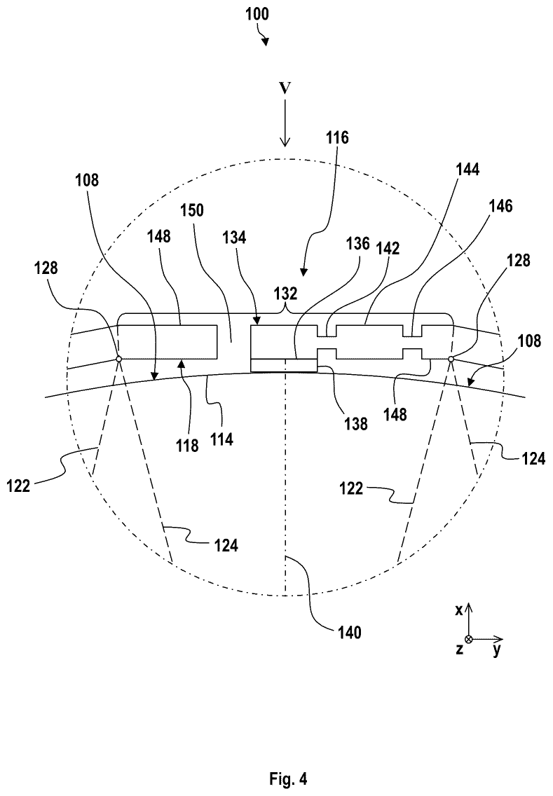

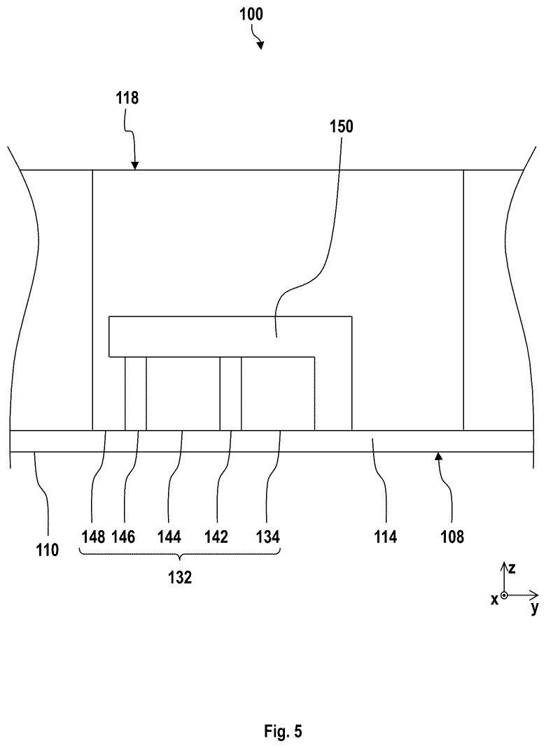

FIG. 4 shows the detail view IV in accordance with FIG. 2. FIG. 5 shows the view V in accordance with FIG. 4. In the following text, reference is made to FIGS. 4 and 5 simultaneously.

The outer ring 118 comprises a plurality of outer ring segments 132, only one of which has been provided with a reference sign in FIG. 4. The outer ring segments 132 are connected to one another in one piece, in particular materially in one piece, at the outer joining points 128. The outer ring segments 132 per se are not curved, but rather straight. A plurality of such outer ring segments 132 form the ring-shaped geometry of the outer ring 118. That is to say, for example, that the outer ring 118 is not circular, but rather polygonal. Only one outer ring segment 132 is discussed in more detail hereinafter.

Each outer ring segment 132 comprises a securing portion 134. The securing portion 134 can also be referred to as a small securing foot. The securing portion 134 is provided centrally between two adjacent stiffening ribs 122, 124. The stiffening ribs 122, 124 begin at the outer joining points 128 centrally between the securing portions 134 of the outer ring segments 132 and run counter to the radial direction R obliquely inwards to the inner ring 120 and are connected thereto with the aid of the inner joining points 130.

The outer surface 114 of the optical element 108 is cohesively connected to the securing portion 134. For this purpose, an adhesive bond 138 is provided between a joining surface 136 of the securing portion 134, the joining surface facing the outer surface 114, and the outer surface 114. The adhesive bond 138 cohesively connects the outer surface 114 to the joining surface 136. The adhesive bond 138 can be for example an epoxy resin or the like. The joining surface is an adhesive bonding surface and can therefore also be referred to as such.

A plurality of securing portions 134 are provided. Accordingly, a plurality of adhesive bonds 138 are provided as well. The outer ring 118 is connected to the optical element 108 only with the aid of the securing portions 134 and the adhesive bonds 138. A normal 140 to the joining surface 136 intersects the centre axis 102. In the present case, a “normal” or a “normal vector” should be understood to mean a perpendicular to the joining surface 136. The stiffening ribs 122, 124 intersect the normal 140 at the inner ring 120, for example at the respective inner joining point 130.

The securing portion 134 is pivotably connected to a connecting portion 144 of the outer ring segment 132 with the aid of a joint portion 142. The joint portion 142 is a flexure. In the present case, a “flexure” should be understood to mean generally a region, for example a cross-sectional narrowing or thinning, of a component, in the present case the outer ring segment 132, which region enables a relative movement between two rigid-body regions of the component by bending or torsion. What function as rigid-body regions here are the securing portion 134 and the connecting portion 144.

By adapting the stiffness of the joint portion 142, the properties thereof, for example the deformability thereof, can be adapted. In the present case, the “stiffness” should be understood to mean very generally the resistance of a body, in the present case the joint portion 142, to an elastic deformation imposed thereon by an external load and conveys the relationship between the load on the body and its deformation. The stiffness is determined by the material of the body and its geometry. For example, the stiffness of the joint portion 142 can be adapted as desired by way of different cross-sectional geometries.

The joint portion 142 enables a movement of the securing portion 134 along the radial direction R outwards away from the inner ring 120. The connecting portion 144 is joined to a base portion 148 of the outer ring segment 132 via a further joint portion 146. The joint portion 146, too, is a flexure. The joint portion 146 is optional. The joint portions 142, 146 can have identical or different stiffnesses.

Facing away from the joint portion 146, an interspace or gap 150 is provided between the base portion 148 and the securing portion 134 and separates the securing portion 134 from the base portion 148. As shown in FIG. 5, the gap 150 extends circumferentially partly around the securing portion 134, the joint portions 142, 146 and the connecting portion 144. The base portion 148 is planar, the gap 150 forming a cutout which, with the aid of the joint portions 142, 146, enables a movement of the securing portion 134 and the connecting portion 144 relative to the base portion 148.

A radial movement of the securing portion 134 is possible with the aid of the joint portions 142, 146. This enables a decoupling of a desired tensioning force for the optical element 108. The securing portion 134 joined to the base portion 148 via the joint portions 142, 146 makes it possible for only very small radial forces to be transmitted to the optical element 108. The mount 116 is joined to the optical element 108 only via the securing portions 134 and the corresponding adhesive bonds 138.

Since the rear side 112 of the optical element 108 need not have defined optical properties, it is possible to use the installation space over the rear side 112 for stiffening the mount 116. For this purpose, the inner ring 120 is positioned over the rear side 112 and stiffened with the aid of the stiffening ribs 122, 124. As a result, the optical system 100 has only a slightly larger installation space than the optical element 108 on its own. The inner ring 120 and the stiffening ribs 122, 124 function as a carrying structure for the outer ring 118. The stiffening ribs 122, 124 are weight-optimized, such that the mount 116 has a high stiffness with at the same time low weight.

Returning now to FIG. 3, the mount 116, for example the outer ring 118, comprises a plurality of vibration absorber interfaces 152, 154, 156. Exactly three vibration absorber interfaces 152, 154, 156 can be provided, arranged in a manner distributed uniformly around the centre axis 102. For example, the vibration absorber interfaces 152, 154, 156 are positioned at the outer ring 118 in a manner offset by 120° with respect to one another.

At each vibration absorber interface 152, 154, 156, a vibration absorber (known as: Tuned Mass Damper, TMD) is provided. Each vibration absorber interface 152, 154, 156 can be provided at one of the outer joining points 128 at which two stiffening ribs 122, 124 meet. As a result, a high stiffness can be attained in the region of the vibration absorber interfaces 152, 154, 156.

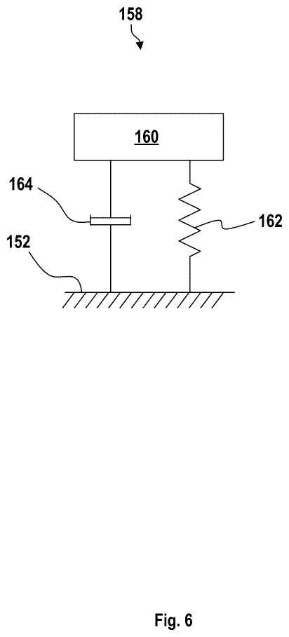

FIG. 6 shows a schematic view of an embodiment of a vibration absorber 158.

Such a vibration absorber 158 can be provided at each vibration absorber interface 152, 154, 156. However, only the vibration absorber interface 152 is discussed below. The vibration absorber 158 comprises an absorber mass 160. The absorber mass 160 can be acurately curved and have a geometry adapted to a geometry of the outer ring 118 of the mount 116. The absorber mass 160 is attached to the outer ring 118 on the outer side as viewed along the radial direction R.

Besides the absorber mass 160, the vibration absorber 158 comprises a spring 162 and a damper 164. The absorber mass 160 is joined to the vibration absorber interface 152 with the aid of the spring 162 and the damper 164. The spring 162 and the damper 164 can be realized for example by an elastically deformable component, for example in the form of an adhesive bond or an elastomer. In this case, the elastically deformable component performs both the spring function of the spring 162 and the damping function of the damper 164.

The absorber mass 160 can vibrate along the x-direction x and along the y-direction y. Along the z-direction z, the absorber mass 160 is positioned at the height of a centre of gravity of the optical system 100. Vibrations of the optical system 100 can be damped with the aid of the vibration absorber 158. A natural frequency of the vibration absorber 158 can be influenced or set for example by variation of the absorber mass 160 and/or variation of the stiffness of the spring 162.

As shown in FIG. 3, the mount 116 comprises a plurality of mount strut interfaces 166, 168, 170 besides the vibration absorber interfaces 152, 154, 156. Exactly three mount strut interfaces 166, 168, 170 can be provided, arranged in a manner distributed uniformly around the centre axis 102. For example, the mount strut interfaces 166, 168, 170 are positioned at the outer ring 118 in a manner offset by 120° with respect to one another. In this case, the mount strut interfaces 166, 168, 170 are arranged centrally between the vibration absorber interfaces 152, 154, 156. Each mount strut interface 166, 168, 170 is assigned an outer joining point 128 at which two stiffening ribs 122, 124 meet. As a result, a high stiffness can also be attained in the region of the mount strut interfaces 166, 168, 170. The mount strut interfaces 166, 168, 170 are arranged at the outer ring 118 on the outer side as viewed along the radial direction R.

Each mount strut interface 166, 168, 170 is assigned a mount strut (not shown). Three mount struts are thus provided. The mount strut is a so-called A strut or can be referred to as such. The mount 116 is seated on six spatial points. In this case, each mount strut is assigned two of these spatial points. With the aid of the mount struts, the mount 116 or the optical system 100 is operatively connected to a fixed world, such as a force frame, for example. In this case, the mount struts mechanically decouple the optical system 100 from the fixed world, such that no unwanted stresses are introduced into the optical system 100.

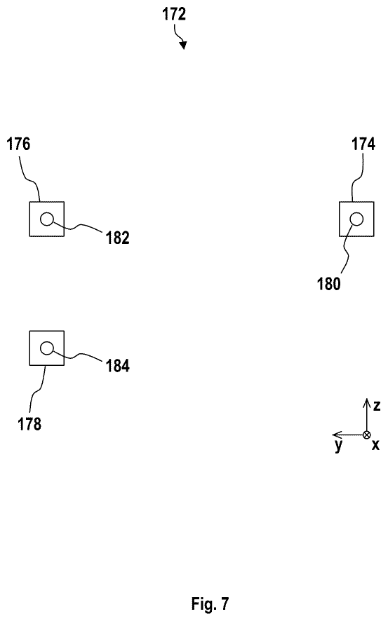

FIG. 7 shows a schematic view of an embodiment of a tool interface 172.

FIG. 7 corresponds to the view VII in accordance with FIG. 6. The view VII looks perpendicularly towards the tool interface 172. Besides the vibration absorber interfaces 152, 154, 156 and the mount strut interfaces 166, 168, 170, the mount 116 furthermore comprises the tool interface 172, to which a tool (not shown) for swapping the optical system 100 from the illumination optical unit 4 can be coupled. The tool interface 172 comprises a first interface surface 174, a second interface surface 176 and a third interface surface 178. The tool bears against the interface surfaces 174, 176, 178. The interface surfaces 174, 176, 178 are provided at the outer ring 118 on the outer side as viewed along the radial direction R.

All the interface surfaces 174, 176, 178 are oriented parallel to one another. In this case, the first interface surface 174 in the orientation in FIG. 7 is set back by a distance a (FIG. 3) in relation to the interface surfaces 176, 178. As viewed along the z-direction z, the first interface surface 174 and the second interface surface 176 are positioned at the same height. As viewed along the z-direction z, the third interface surface 178 is positioned below the interface surfaces 174, 176. Each interface surface 174, 176, 178 is assigned a threaded hole 180, 182, 184. Each threaded hole 180, 182, 184 is positioned centrally at the interface surface 174, 176, 178 assigned to it. With the aid of the threaded holes 180, 182, 184, the tool can be connected to the tool interface 172 in order to swap the optical system 100.

The optical system 100 is thus easily swappable. Owing to the compact design of the mount, little installation space is used for the optical system 100. A positioning accuracy of a few μm can be achieved. With the aid of the securing portions 134 joined to the outer ring 118 via the joint portions 142, 146, a decoupling of the tensioning force is possible such that only tiny deformations are transmitted. With the aid of the stiffening ribs 122, 124, the total stiffness of the optical system 100 can be increased in the context of increased demands regarding a travel of the optical system 100 and with installation space becoming smaller.

Although the present disclosure has been described on the basis of exemplary embodiments, it is modifiable in diverse ways.

### LIST OF REFERENCE SIGNS

1 Projection exposure apparatus
2 Beam shaping and illumination system
4 Projection optical unit
6 Light source
8 Radiation
10 Photomask
12 Wafer
14 Lens element
16 Lens element
18 Lens element
20 Mirror
22 Mirror
24 Optical axis
26 Medium
100 Optical system
102 Centre axis
104 Half axis
106 Half axis
108 Optical element
110 Optically effective surface
112 Rear side
114 Outer surface
116 Mount
118 Outer ring
120 Inner ring
122 Stiffening rib
124 Stiffening rib
126 Interspace
128 Joining point
130 Joining point
132 Outer ring segment
134 Securing portion
136 Joining surface
138 Adhesive bond
140 Normal
142 Joint portion
144 Connecting portion
146 Joint portion
148 Base portion
150 Gap
152 Vibration absorber interface
154 Vibration absorber interface
156 Vibration absorber interface
158 Vibration absorber
160 Absorber mass
162 Spring
164 Damper
166 Mount strut interface
168 Mount strut interface
170 Mount strut interface
172 Tool interface
174 Interface surface
176 Interface surface
178 Interface surface
180 Threaded hole
182 Threaded hole
184 Threaded hole
a Distance
R Radial direction
U Circumferential direction
x x-direction
y y-direction
z z-direction

What is claimed is:

1. An optical system, comprising:
an optical element; and
a mount carrying the optical element,
wherein:
the mount comprises an outer ring in which the optical element is accommodated at least in portions;
the outer ring comprises securing portions cohesively connected to the optical element;
the securing portions are pivotably connected to the outer ring via joint portions; and
the mount comprises a tool interface configured to releasably secure a tool configured to swap the optical system from a unit containing the optical system.

2. The optical system of claim 1, wherein the joint portions are configured to enable a pivot movement of the securing portions in a radial direction of the optical system.

3. The optical system of claim 1, wherein:
each securing portion comprises a joining surface facing the optical element, the joining surface being cohesively connected to the optical element; and
normals to the joining surfaces intersect one another in a centre axis of the optical system.

4. The optical system of claim 1, wherein each securing portion is pivotably connected to the outer ring via a first joint portion and a second joint portion different from the first joint portion.

5. The optical system of claim 4, wherein each securing portion is pivotably connected to a connecting portion via the first joint portion, and the connecting portion is pivotably connected to the outer ring via the second joint portion.

6. The optical system of claim 1, wherein:
the optical element comprises an optically effective surface, a rear side facing away from the optically effective surface, and an outer surface extending circumferentially around the optical element; and
the securing portions are only cohesively connected to the outer surface.

7. The optical system of claim 6, wherein the optically effective surface is a mirror surface.

8. The optical system of claim 1, wherein the mount comprises an inner ring within the outer ring, and the inner ring is connected to the outer ring via stiffening ribs.

9. The optical system of claim 8, wherein two stiffening ribs are connected to the outer ring at a common outer joining point.

10. The optical system of claim 9, wherein the outer joining points and the securing portions alternate.

11. The optical system of claim 9, wherein each securing portion is positioned centrally between two adjacent outer joining points.

12. The optical system of claim 9, wherein two stiffening ribs are connected to the inner ring at a common inner joining point, and the outer joining points and the inner joining points alternate.

13. The optical system of claim 1, wherein the mount comprises vibration absorber interfaces configured to join vibration absorbers to the mount.

14. The optical system of claim 1, wherein the mount comprises mount strut interfaces configured to join mount struts to the mount.

15. The optical system of claim 1, wherein the unit is a projection optical unit.

16. The optical system of claim 1, wherein the unit is an illumination optical unit.

17. The optical system of claim 1, wherein:
the joint portions are configured to enable a pivot movement of the securing portions in a radial direction of the optical system;
each securing portion comprises a joining surface facing the optical element, the joining surface being cohesively connected to the optical element; and
normals to the joining surfaces intersect one another in a centre axis of the optical system.

18. An apparatus, comprising:
an optical system according to claim 1,
wherein the apparatus is a lithography projection exposure apparatus.

19. The apparatus of claim 18, comprising a projection optical unit, wherein the projection optical unit comprises the optical system.

20. The apparatus of claim 18, comprising an illumination optical unit, wherein the illumination optical unit comprises the optical system.
